(19) United States
(12) Patent Application Publication
(10) Pub. No.: US 2010/0053646 A1
(43) Pub. Date: Mar. 4, 2010

(54) IMAGE DENSITY CONTROL DEVICE AND IMAGE FORMING APPARATUS

(76) Inventors: Shunichiro Shishikura, Kanagawa (JP); Naoya Yamasaki, Kanagawa (JP); Toru Yoshida, Tokyo (JP)

Correspondence Address: MORGAN LEWIS & BOCKIUS LLP, 1111 PENNSYLVANIA AVENUE NW, WASHINGTON, DC, 20004, US

(21) Appl. No.: 12/482,891

(22) Filed: Jun. 11, 2009

(30) Foreign Application Priority Data
Aug. 26, 2008 (JP) P2008-216534

(51) Int. Cl. H04N 1/60; G03F 3/08

(52) U.S. Cl. 358/1.9; 358/518

(57) ABSTRACT

An image density control device includes: a light irradiation unit that irradiates an irradiation light of a wave-length, in which reflectance of a second color layer is higher than reflectance of a first color layer, onto an image which is a laminated layer image formed by an image forming unit on an image carrier and formed out of the first color layer and the second color layer laminated on the first color layer; a detection unit that detects a quantity of a reflection light reflected on the laminated layer image irradiated by the irradiation light from the light irradiation unit; and a control unit that controls density of the image according to the quantity of the reflection light detected by the detection unit.

### CROSS-REFERENCE TO RELATED APPLICATION

This application is based on and claims priority under 35 USC 119 from Japanese Patent Application No. 2008-216534 filed Aug. 26, 2008.

### BACKGROUND

### Technical Field

The present invention relates to an image density control device and an image forming apparatus.

### SUMMARY

According to an aspect of the invention, an image density control device includes: a light irradiation unit that irradiates an irradiation light of a wave-length, in which reflectance of a second color layer is higher than reflectance of a first color layer, onto an image which is a laminated layer image formed by an image forming unit on an image carrier and formed out of the first color layer and the second color layer laminated on the first color layer; a detection unit that detects a quantity of a reflection light reflected on the laminated layer image irradiated by the irradiation light from the light irradiation unit; and a control unit that controls density of the image according to the quantity of the reflection light detected by the detection unit.

According to the aspect of the invention, compared with a case in which the constitution of the present invention is not provided, density of a coloring matter can be highly accurately controlled without being affected by reflection light sent from an image carrier.

### BRIEF DESCRIPTION OF THE DRAWINGS

Exemplary embodiments of the invention will be described in detail based on the following figures, wherein:

FIG. 1 is an overall arrangement view showing an outline of the image forming apparatus of the first exemplary embodiment of the present invention;

FIG. 2 is a view showing reflection characteristics of toner of yellow (Y), magenta (M), cyan (C) and black (K);

FIG. 3 is a sectional view showing an example of the constitution of the density detecting portion;

FIG. 4A is a sectional view of the toner pattern;

FIG. 4B is an upper view of the toner pattern;

FIG. 5A is a view showing an example of the output outputted by the density detecting portion in the case where a surface of the intermediate transfer belt is irradiated with irradiation light;

FIG. 5B is a view showing an example of the output outputted by the density detecting portion in the case where a laminated layer toner patch is irradiated with irradiation light;

FIG. 5C is a view showing an example of the output outputted by the density detecting portion in the case where a single layer toner patch is irradiated with irradiation light;

FIG. 6 is a block diagram showing an example of the control system of the image forming apparatus of the first exemplary embodiment of the present invention;

FIG. 7 is a view showing a relation between the image density (the axis of abscissa) and the output value (the axis of ordinate) of the density detecting portion;

FIG. 8 is a flow chart showing an example of the action of the image forming apparatus of the first exemplary embodiment of the present invention;

FIG. 9A is a view showing an example of the output outputted by the density detecting portion in the case where a surface of the intermediate transfer belt is irradiated with irradiation light;

FIG. 9B is a view showing an example of the output outputted by the density detecting portion in the case where a laminated layer toner patch is irradiated with irradiation light;

FIG. 9 is a view showing an example of the output outputted by the density detecting portion in the case where a single layer toner patch is irradiated with irradiation light;

FIG. 10 is a block diagram showing an example of the control system of the image forming apparatus of the second exemplary embodiment of the present invention;

FIG. 11 is a flow chart showing an example of the action of the image forming apparatus of the second exemplary embodiment of the present invention;

FIG. 12A is a view showing an example of the output outputted by the density detecting portion in the case where a surface of the intermediate transfer belt is irradiated with irradiation light.

FIG. 12B is a view showing an example of the output outputted by the density detecting portion in the case where a single layer toner patch is irradiated with irradiation light.

FIG. 12C is a view showing an example of the output outputted by the density detecting portion in the case where a laminated layer toner patch for calculating a coefficient is irradiated with irradiation light.

FIG. 12D is a view showing an example of the output outputted by the density detecting portion in the case where a laminated layer toner patch for correcting density is irradiated with irradiation light;

FIG. 13 is a block diagram showing an example of the control system of the image forming apparatus of the third exemplary embodiment of the present invention;

FIG. 14 is a view showing a relation between the image density (the axis of abscissa) and the output value (the axis of ordinate) of the density detecting portion; and

FIG. 15 is a flow chart showing an example of the action of the image forming apparatus of the third exemplary embodiment of the present invention.

### DETAILED DESCRIPTION

An image density control device of an exemplary embodiment of the present invention comprises: a light irradiation unit for irradiating light of the wave-length, in which the reflectance of a second color layer is higher than the reflectance of a first color layer, onto an image which is a laminated layer image formed by an image forming unit on an image carrier and formed out of the first color layer and the second color layer laminated on the first color layer; a detection unit for detecting a quantity of reflection light reflected on the laminated layer image by the irradiation of the irradiation light sent from the light irradiation unit; and a control unit for controlling density of the image, which is formed on the image carrier by the image forming unit, according to the quantity of reflection light detected by the detection unit.

The terminology of the reflection described above includes both the normal reflection and the diffusion reflection as long as no specific description is made.

Instead of the detection unit and the control unit described above, the image density control device may include a first detection unit for detecting a quantity of the first reflection light from the reflection light reflected in the normal reflecting direction on the laminated layer image by the irradiation of light sent from the light irradiation unit; a second detection unit for detecting a quantity of the second reflection light from the reflection light reflected in the diffusion reflecting direction on the laminated layer image by irradiation of the irradiation light sent from the light irradiation unit; and a control unit for controlling density of the image formed on the image carrier by the image forming unit according to quantities of the first and the second reflection light respectively detected by the first and the second detection unit.

The above laminated layer image is formed out of, for example, the first color layer made of a coloring material of black (K) and the second color layer made of at least one coloring matter in the coloring matters of yellow (Y), magenta (M) and cyan (C). Irradiation light sent from the light irradiation unit described above may be infrared light, the wave-length of which is, for example, 700 nm to 1 mm.

Examples of the image carrier are: a photoreceptor, an intermediate transfer body and a sheet. As long as it can carry an image, the image carrier is not limited to the above specific examples.

In the above constitution, when the irradiation light sent from the light irradiation unit is irradiated onto a laminated layer image formed by the image forming unit, the irradiation light is reflected on the second color layer, the reflectance of which is higher than that of the first color layer, and the irradiation light, which has been transmitted through the second color layer, is absorbed by the first color layer. Therefore, the irradiation light does not reach a surface of the image carrier. Due to the foregoing, the detection unit detects a quantity of reflection light reflected on the second color layer without being affected by the reflection light reflected on the surface of the image carrier. The control unit controls the image forming unit by using a quantity of the reflection light. Accordingly, an image of high quality, on which the second coloring matter is used, can be formed by the image forming unit.

### First Exemplary Embodiment

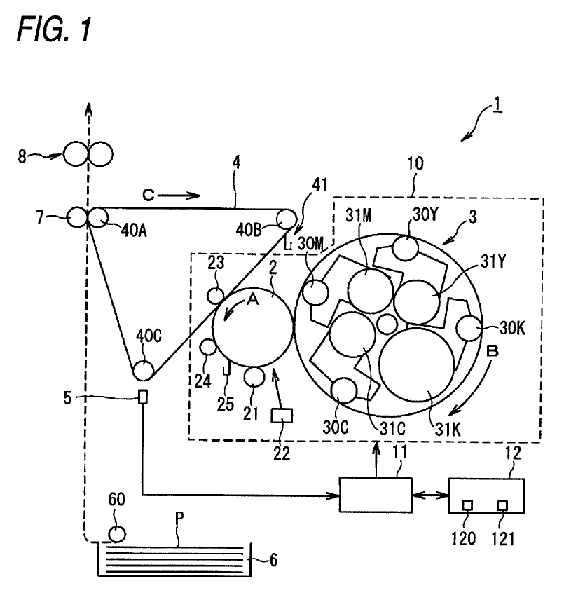

FIG. 1 is an arrangement view showing an outline of the image forming apparatus of the first exemplary embodiment of the present invention. This image forming apparatus 1 includes: an intermediate transfer belt (image carrier) 4 for carrying a toner image which is an image; an image forming unit (image forming unit) 10 for forming a toner image on the intermediate transfer belt 4; a density detection portion 5 which functions as a light irradiation unit for irradiating light onto the toner image formed on the intermediate transfer belt 4 and also functions as a detection unit for detecting intensity of reflection light reflected on the toner image; and a control portion (control unit) 11 for controlling density of the toner image formed on the intermediate transfer belt 4 by the image forming unit 10 according to a quantity of reflection light detected by the density detection portion 5.

The image forming apparatus 1 includes: a sheet supplying cassette 6 for accommodating plural of sheets P and for supplying the sheets P through the sheet supplying roller 60; a secondary transfer roller 7 which is arranged at a position (secondary transfer position) opposed to the supporting roller 40A described later with respect to the intermediate transfer belt 4 and for transferring the image from the intermediate transfer belt 4 onto the sheet P; and a fixing portion 8 for fixing a toner image which has been transferred onto the sheet P.

Image Forming Unit

The image forming unit 10 includes: a photoreceptor drum 2, on the surface of which a photosensitive layer is provided; and a so-called rotary type developing unit 3 for developing an electrostatic latent image formed in the photoreceptor drum 2 into a toner image of plural of colors of yellow (Y), magenta (M), cyan (C) and black (K).

The photoreceptor drum 2 is provided with a rotary mechanism not shown and rotated in the arrow direction A. There are provided a charging unit 21 for giving a predetermined electric charge to the photoreceptor drum 2 before exposure, an exposure portion 22 for exposing the photoreceptor drum 2 by a laser beam modulated according to image data of each color (Y, M, C, K) so that an electrostatic latent image can be formed, a primary transfer roller 23, which is arranged at a position (primary transfer position) opposed to the photoreceptor drum 2 with respect to the intermediate transfer belt 4, for transferring a toner image, which has been developed onto the photoreceptor drum 2 by the developing unit 3, on the intermediate transfer belt 4, a discharging unit 24 for discharging the photoreceptor drum 2, and a drum cleaning portion 25 for removing the remaining toner from the photoreceptor drum 2. These components are arranged in the periphery of the photoreceptor drum 2.

Toner images of the respective colors, which are formed in order on a surface of the photoreceptor drum 2 by the developing unit 3, are primarily transferred onto the intermediate transfer belt 4 being superimposed.

The developing unit 3 has a rotary mechanism not shown in the drawing and rotated in the direction of the arrow B. The developing unit 3 includes: developing rollers 30K, 30Y, 30M, 30C for developing an electrostatic latent image, which has been formed on the photoreceptor drum 2 by the exposure portion 22, by the toner of each color; and toner cartridges 31K, 31Y, 31M, 31C for accommodating toner of each color and supplying the toner to the corresponding developing rollers 30K, 30Y, 30M, 30C.

Intermediate Transfer Belt

The intermediate transfer belt 4 includes: supporting rollers 40A to 40C which rotate the intermediate transfer belt in the direction of the arrow C and pivotally support the intermediate transfer belt 4 by a predetermined tension; and a belt cleaning portion 41 for removing the toner remaining on a surface of the intermediate transfer belt 4 and also removing patches of sheet P with a brush and blade.

Density Detection Portion

The density detection portion 5 irradiates irradiation light onto a surface of the intermediate transfer belt 4 and onto an object to be detected such as a toner pattern described later formed on the intermediate transfer belt 4 by the image forming unit 10. The density detection portion 5 detects reflection light reflected on the object to be detected and outputs an output value corresponding to a quantity of light of the thus detected reflection light. In this connection, the output value may be a value of voltage or electric current. However, the output value is not limited to the above specific value.

Control Portion

The control portion 11 is realized, for example, by an arithmetic circuit such as CPU. According to the output values outputted from the intermediate transfer belt 4 surface and the toner pattern detected by the density detection portion 5, the control portion 11 controls image density at the time of forming a toner image on the intermediate transfer belt 4 by the image forming unit 10. In this connection, the density detection portion 5 and the control portion 11 compose an image density control device.

Memory

The memory 12 is a storage portion realized, for example, by ROM, RAM and a hard disk. The memory 12 stores: pattern image data 120 used at the time of forming a toner pattern; and reference output value information 121 which is a reference at the time of detecting the image density and in which a correlation between the image density at the time of forming a pattern and the output value of the density detection portion 5 is established. In this connection, the reference output value information 121 may be a table on which the image density and the output value are related to each other. Further, the reference output value information 121 may be a calculating expression of calculating one of the image density and the output value from the other of the image density and the output value. However, the reference output value information 121 is not limited to the above specific example.

Reflection Characteristic of Toner

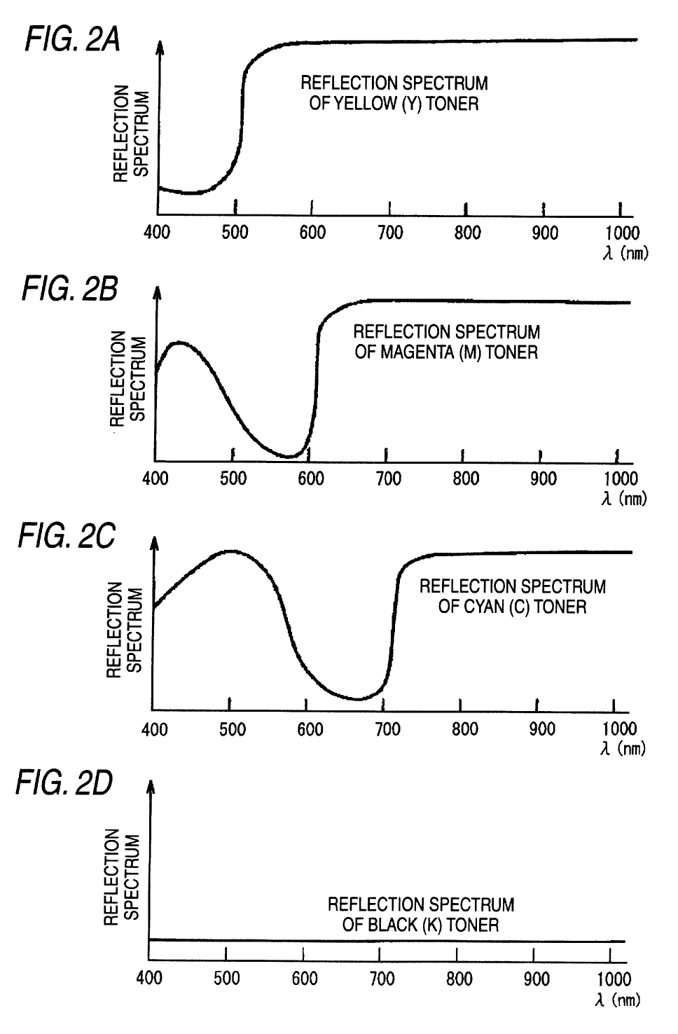

FIGS. 2A to 2D are graphs respectively showing reflection characteristics of toner of yellow (Y), magenta (M), cyan (C) and black (K) accommodated in the toner cartridges 31K, 31Y, 31M, 31C. The reflection characteristic of each toner is described as follows. The reflectance of yellow toner is low in the wave-length region of about 400 to 500 nm, the reflectance of magenta toner is low in the wave-length region of about 500 to 600 nm, and the reflectance of cyan toner is low in the wave-length region of about 600 to 700 nm. In the wave-length regions except for the above wave-length regions, the reflectance of each toner is increased. On the other hand, the reflection characteristic of the black toner is that the reflectance is low in all the wave-length regions. In this connection, the wave-length region, the reflectance of which is high, is referred to as a light reflection region.

Detailed Constitution of Density Detection Portion

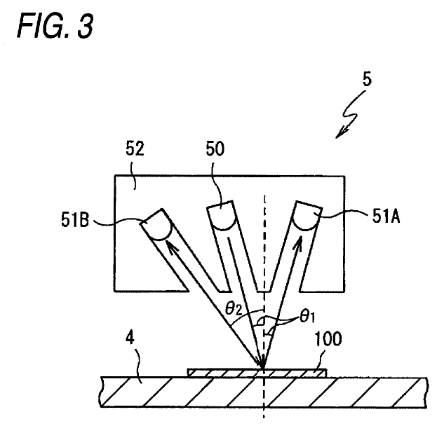

FIG. 3 is a sectional view showing an example of the constitution of the density detection portion. This density detection portion 5 includes: a light emitting element (light irradiation unit) 50 for irradiating light onto an object to be detected; a first light receiving element (first detection unit) 51A for receiving reflection light reflected on the object to be detected in the normal reflecting direction; a second light receiving element (second detection unit) 51B for receiving reflection light reflected on the object to be detected in the diffusion reflecting direction; and a housing 52 for accommodating the light emitting element 50 and the first and the second light receiving element 51A, 51B while the housing 52 is cutting off noise light coming from the outside.

The light emitting element 50 is arranged at a position so that the irradiation light emitted from this light emitting element 50 can form an angle θ1 with respect to the vertical line of the intermediate transfer belt 4. For example, the light emitting element 50 is composed of a light emitting diode (LED). In the present exemplary embodiment, the wave-length of light emitted from the light emitting element 50 is in the light reflecting region of the toner of yellow, magenta and cyan. For example, the light emitting element 50 irradiates infrared light, the wave-length of which is approximately 930 nm.

The first light receiving element 51A is arranged at a position, being opposed to the light emitting element 50, at which the first light receiving element 51A forms an angle θ1 with respect to the vertical line of the intermediate transfer belt 4. The second light receiving element 51B is arranged at a position at which the second light receiving element 51B forms an angle θ2 with respect to the vertical line of the intermediate transfer belt 4. Each of the first and the second light receiving element 51A, 51B is formed out of, for example, a photo-diode (PD) and outputs an output value corresponding to the intensity of the reflection light received.

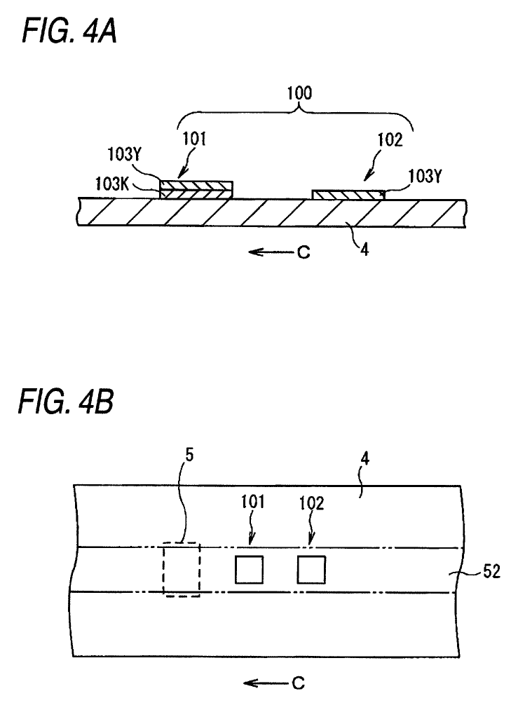

FIG. 4A is a sectional view of the toner pattern. FIG. 4B is an upper view of the toner pattern. The toner pattern 100 is a toner image formed on the intermediate transfer belt 4 by the image forming unit 10. The toner pattern 100 includes a laminated layer toner patch (laminated layer toner image) 101 of two layers and a single layer toner patch (single layer image) 102 of one layer.

The laminated layer toner patch 101 is formed in such a manner that, for example, the yellow toner layer (the second color layer) 103Y made of yellow toner is laminated on the black toner layer (the first color layer) 103K made of black toner. The single layer toner patch 102 is formed out of a yellow toner layer 103Y. The image density (Cin) on the black toner layer 103K is 100%. The image density on the yellow toner layer 103Y is not limited to 100% but the yellow toner layer 103Y is formed so that the image density can be a specific value designated by the control portion 11. As exemplarily shown in FIG. 4B, the toner pattern 100 is arranged in a detection range 53 which is a range irradiated by the irradiation light sent from the light receiving element 51 of the density detecting portion 5.

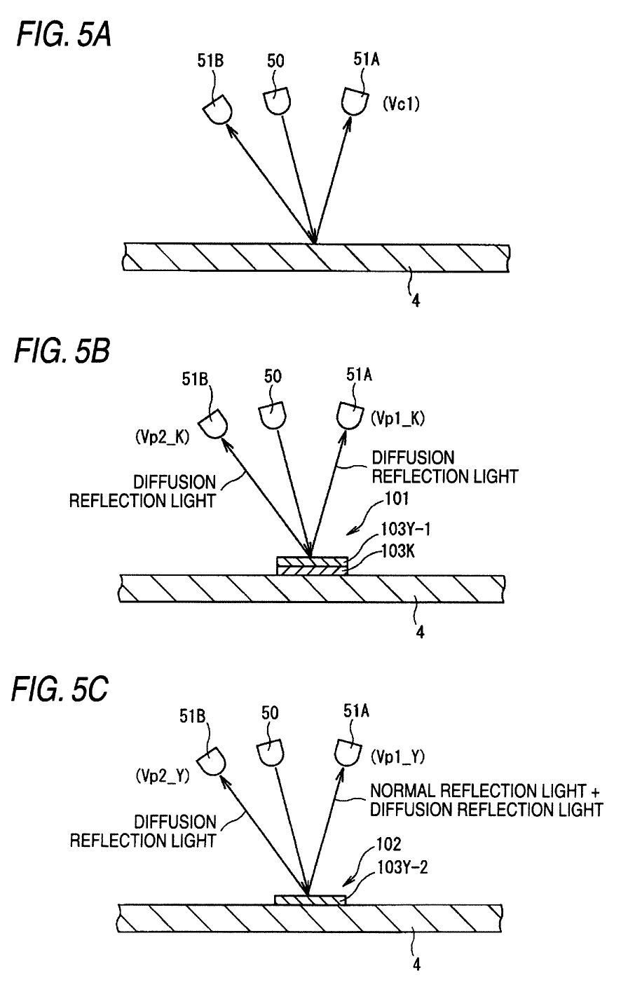

FIGS. 5A to 5C are views showing examples of the output by the density detecting portion in the case where the surface of the intermediate transfer belt, the laminated layer toner patch and the single layer toner patch are respectively irradiated with irradiation light.

In FIG. 5A, in the case where the light emitting element 50 irradiates light onto a surface of the intermediate transfer belt 4 onto which toner is not transferred, the first light receiving element 51A receives reflection light reflected on the surface of the intermediate transfer belt 4 and detects the output value Vc1 showing the light intensity of the reflection light.

The yellow toner layer 103Y-1 of the laminated layer toner patch 101 exemplarily shown in FIG. 5B is formed by the image forming unit 10 so that the image density can be 100% or the saturation density D1 close to 100%. In the case where this laminated layer toner patch 101 is irradiated with irradiation light, the irradiation light, which has transmitted through the yellow toner layer 103Y-1, or the irradiation light, which has passed through a portion of no yellow toner in the toner patch in the case where the yellow toner layer is formed by the intermediate density expressed by the area gradation, is absorbed by the black toner layer 103K and does not reach the intermediate transfer belt 4. Accordingly, the irradiation light is not reflected on the intermediate transfer belt 4. Therefore, the first and the second light receiving element 51A, 51B respectively receive the diffusion reflecting light reflected on the yellow toner layer 103Y. Then, an output value (a quantity of light of the first reflection light) Vp1_K showing the light intensity of the diffusion reflecting light and an output value (a quantity of light of the second reflection light) Vp2_K are respectively detected.

The yellow toner layer 103Y-2 of the single layer toner patch 102 exemplarily shown in FIG. 5C is formed, for example, by the intermediate density D2 of 50% which is a predetermined image density. In the case where this single layer toner patch 102 is irradiated with the irradiation light, the irradiation light transmitted through the yellow toner layer 103Y-2 is reflected on the intermediate transfer belt 4 as the normal reflection light. Therefore, the first light receiving element 51A receives the normal reflection light reflected on the intermediate transfer belt 4 and the diffusion reflection light reflected on the yellow toner layer 103Y-2 and detects an output value (a quantity of light of the third reflection light) Vp1_Y showing the light intensity of the reflection light. The second light receiving element 51B receives the diffusion reflecting light reflected on the yellow toner layer 103Y-2 and detects an output value (a quantity of light of the fourth reflection light) Vp2_Y showing the light intensity of the diffusion reflecting light.

Detailed Constitution of Control Portion

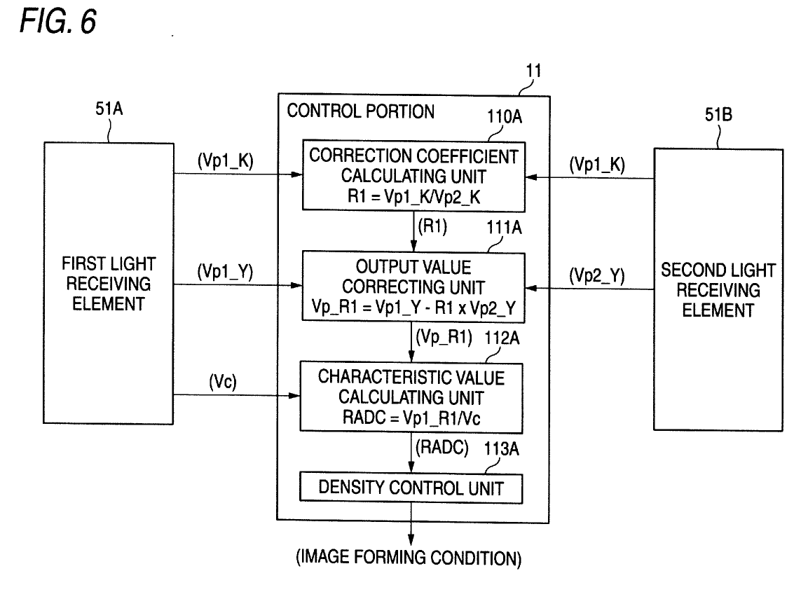

FIG. 6 is a block diagram showing an example of the control system of the image forming apparatus. The control portion 11 includes: a correction coefficient calculating unit 110A; an output value correction unit 111A; a characteristic value calculating unit 112A; and a density control unit 113A.

Correction Coefficient Calculating Means

Into the correction coefficient calculating unit 110A, the output values Vp1_K, Vp2_K, which are outputted according to the laminated layer toner patch 101, are inputted from the first and the second light receiving element 51A, 51B. As shown by the following expression (1), the correction coefficient calculating unit 110A calculates the sensitivity correction coefficient R1 when the output value Vp1_K is divided by the output value Vp2_K.

R1=Vp1_{—}K/Vp2_{—}K Expression (1)

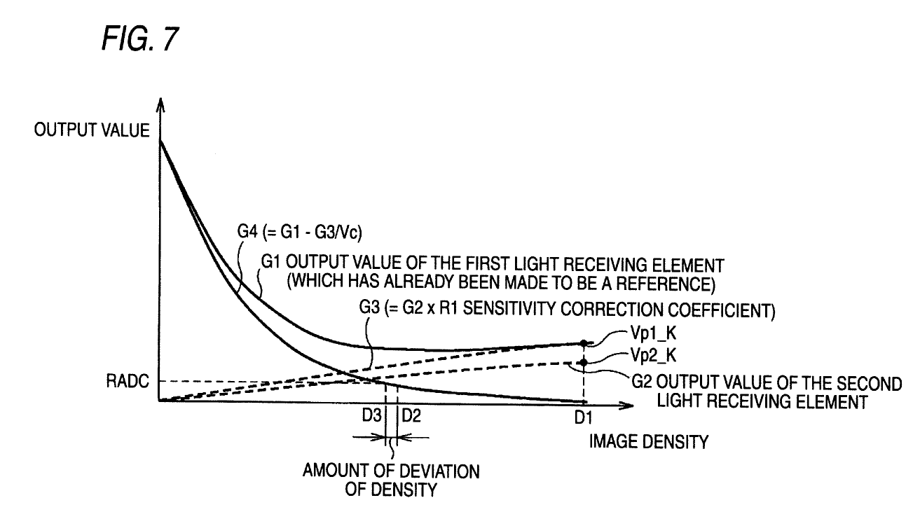

FIG. 7 is a view showing a relation between the image density (the axis of abscissa) and the output value (the axis of ordinate) of the density detecting portion. The graphs G1 and G2 are output values which are the reference sensitivities of the first and the second light receiving element 51A, 51B stored in the memory 12 as the reference output value information 121. In this case, the output values Vp1_K, Vp2_K are output values according to the reflection light sent from the yellow toner layer 103Y-1 of the saturation density D1 of the laminated layer toner patch 101, these output values are respectively plotted on the graphs G1 and G2.

That is, the correction coefficient calculating unit 110A corrects an output value of the second light receiving element 51B so that the output value of the second light receiving element 51B can be the same as the output value of the first light receiving element 51A. Accordingly, in FIG. 7, when the entire graph G2 is multiplied by the sensitivity correction coefficient R1, an inclination of the graph G2 is corrected and the graph G3 crossing the graph G1 at the output value Vp1_K can be obtained.

In this connection, the correction coefficient calculating unit 110A may correct an output value of the first light receiving element 51A. Alternatively, the correction coefficient calculating unit 110A may correct both output values of the first and the second light receiving element 51A, 51B. The correction coefficient calculating unit 110A may send the sensitivity correction coefficient R1 to the density detecting portion 5 so as to use it for adjusting gain of the second light receiving element 51B.

Output Value Correcting Means

Into the output value correcting unit 111A, the output values Vp1_Y, Vp2_Y, which are outputted according to the single layer toner patch 102, are inputted from the first and the second light receiving element 51A, 51B. As shown in the following expression (2), the output value correcting unit 111A calculates the correction output value Vp_R when the output value Vp1_Y is corrected by using the sensitivity correcting coefficient R1, which is calculated by the correction coefficient calculating unit 110A, and by using the output value Vp2_Y.

Vp_{—}R=Vp1_{—}Y−R1×Vp2_{—}Y Expression (2)

Characteristic Value Calculation Means

Into the characteristic value calculation unit 112A, the output value Vc1 according to the surface of the intermediate transfer belt 4 is inputted from the first light receiving element 51A. As shown in the following expression (3), the characteristic value calculating unit 112A calculates the detection characteristic value RADC, in which the correction output value Vp_R is made to be a standard, when the correction output value Vp_R corrected by the output value correcting unit 111A is divided by the output value Vc1.

RADC=Vp_{—}R/Vc1 Expression (3)

The detection characteristic value RADC calculated by the characteristic value calculating unit 112A is plotted onto the graph G4 obtained when the graph G3 is subtracted from the graph G1 shown in FIG. 7 and further divided by the output value Vc1. In this graph G4, a relation between the image density and the output value in all the density region from the low image density region to the high image density region is a corresponding relation of one to one. Therefore, in all the density region containing the high density, the image density can be detected.

Density Control Means

The density control unit 113A calculates an amount of deviation of density from a difference between the detection density D3 corresponding to the detection characteristic value RADC calculated by the characteristic value calculating unit 112A and the intermediate density D2 at the time of forming the yellow toner layer 103Y-2. Then, the density control unit 113A corrects an image forming condition of the image forming unit 10 so that an amount of deviation of density can be reduced.

Examples of the image forming conditions are: a charging condition at the time of electrically charging the photoreceptor drum 2 with the charging unit 21; an exposure condition at the time of exposing the photoreceptor drum 2 with the exposure portion 22; and a developing condition at the time of developing an electrostatic latent image, which is formed on the photoreceptor drum 2, into a toner image with the developing unit 3. In this connection, the density control unit 113A may correct a content of image data before an image signal based on the image data is sent to the image forming unit 10. In this connection, in the present exemplary embodiment, the laminated layer toner patch 101 and the single layer toner patch 102 are made of yellow toner and the density of yellow toner is detected. However, the density control unit 113A may correct only the image forming condition related to the yellow toner. Alternatively, the density control unit 113A may correct the image forming conditions related to the magenta and cyan toner which are the other toner.

As described above, the control unit 11 corrects the output value Vp2_Y outputted from the second light receiving element 51B by the above expressions (1) and (2) by using the output value Vp1_K outputted from the first light receiving element 51A and also by using the output value Vp2_K outputted from the second light receiving element 51B and controls the density of the image according to the thus corrected correction output value Vp_R.

Actions of Image Forming Apparatus

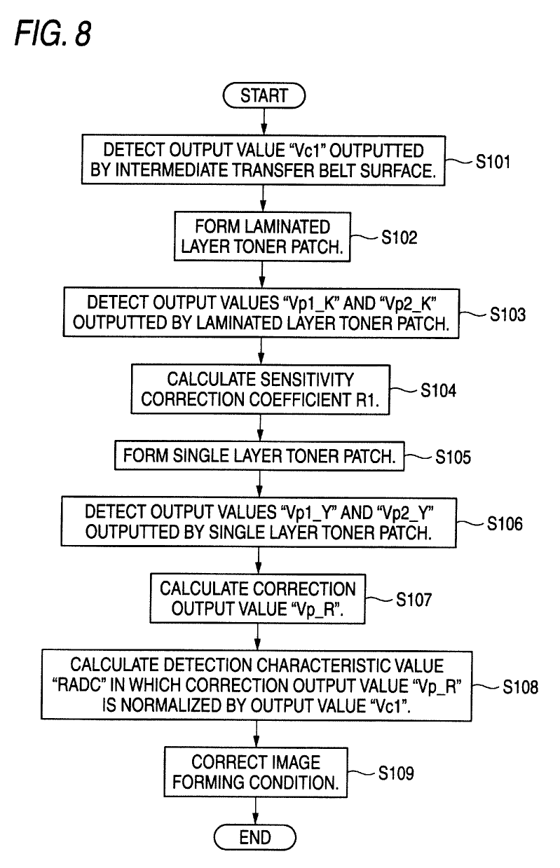

Next, referring to the flow chart shown in FIG. 8, an example of the actions of the image forming apparatus 1 will be explained below. When the control portion 11 detects a predetermined adjustment timing, the control portion 11 executes the correction processing of the image density. Examples of the adjustment timing are: the time at which the electric power source has been turned on; the time at which the components such as a toner cartridge have been replaced; the time at which a predetermined number of sheets of paper P have been outputted; and the time at which a predetermined period of time gas passed.

As exemplarily shown in FIG. 5A, the density detecting portion 5 makes the light emitting element 50 irradiate the irradiation light onto a surface of the intermediate transfer belt 4 onto which toner is not transferred. Then, the density detecting portion 5 detects the output value Vc1 of the reflection light reflected on the surface of the intermediate transfer belt 4 (S101 in FIG. 8)

Next, the control portion 11 controls the image forming unit 10 and forms a laminated layer toner patch 101, which is exemplarily shown in FIG. 5B, on the intermediate transfer belt 4 (S102).

Specifically, the control portion 11 reads out the pattern image data 120 from the memory 12 and sends a pattern image signal, which is based on the pattern image data 120, to the exposure portion 22. Then, the photoreceptor drum 2 is rotated and electrically charged by the charging unit 21. After that, the photoreceptor drum 2 is exposed to a laser beam based on the pattern image signal sent from the exposure portion 22, so that an electrostatic latent image can be formed on a surface of the photoreceptor drum 2. The electrostatic latent image is developed by the black developing roller 30K into a black toner image, so that the black toner layer 103K can be formed on the intermediate transfer belt 4. In the same manner, a yellow electrostatic latent image is formed on the surface of the photoreceptor drum 2 by the charging unit 21 and the exposure portion 22. Then a yellow toner image is developed by the yellow developing roller 30Y. The yellow layer 103Y-1 is laminated on the black toner layer 103K formed on the intermediate transfer belt 4. In this way, the laminated layer toner patch 101 is formed.

The light emitting element 50 of the density detecting portion 5 irradiates the irradiation light onto the laminated layer toner patch 101 formed on the intermediate transfer belt 4. The first and the second light receiving element 51A, 51B respectively detect the output values Vp1_K, Vp2_K of the reflection light sent from the lamination toner patch 101 (S103). Then, the correction coefficient calculating unit 110A calculates the sensitivity correcting coefficient R1 by the above expression (1) by using the thus detected output values Vp1_K, Vp2_K (S104).

Next, the control portion 11 controls the image forming unit 10 and forms the single layer toner patch 102, which is exemplarily shown in FIG. 5C, on the intermediate transfer belt 4 (S105). Then, the first and the second light receiving element 51A, 51B respectively detect the output values Vp1_Y, Vp2_Y based on the reflection light sent from the single layer toner patch 102 (S106).

Next, the output value correcting unit 111A calculates the correction output value Vp_R by the above expression (2) by using the detected output values Vp1_Y, Vp2_Y and the sensitivity correcting coefficient R1 (S107).

The characteristic value calculating unit 112A calculates the detection characteristic value RADC by the above expression (3) from the correction output value Vp_R calculated by the output value correcting unit 111A (S108). The density control unit 113A corrects the image forming condition of the image forming unit 10 according to the detection characteristic value RADC (S109). In this way, the correction processing of the image density is completed.

After that, when image data is inputted, the control portion 11 forms an image according to the image data under the condition that the image forming condition is corrected in step S109 described above. That is, the photoreceptor drum 2 is electrically charged by the charging unit 21 and an electrostatic latent image is formed by the exposure portion 22 according to the output image. The electrostatic latent image is developed into the toner images of colors by the developing rollers 30K, 30Y, 30M, 30C. The toner image developed on the photoreceptor drum 2 is transferred onto the intermediate transfer belt 4 by the primary transfer roller 23. When a sheet of paper P is supplied from the sheet supplying cassette 6 by the sheet supplying roller 60, the toner image on the intermediate transfer belt 4 is transferred onto the sheet of paper P by the secondary transfer roller 7 and fixed by the fixing portion 8. After that, the sheet of paper P is discharged from the image forming apparatus 1.

### Second Exemplary Embodiment

The density detecting portion 5 of the image forming apparatus 1 of the first exemplary embodiment has the first and the second light receiving element 51A, 51B. On the other hand, the density detecting portion 5 of the image forming apparatus 1 of the present exemplary embodiment has one light receiving element arranged in the normal reflecting direction and the control portion 11 corrects an output value outputted by the single layer toner patch by using the output value outputted by the laminated layer toner patch detected by the density detecting portion 5. According to the corrected output value outputted by the single layer toner patch, the image density is controlled. The other basic constitution of the second exemplary embodiment is the same as that of the first exemplary embodiment.

Density Detecting Portion

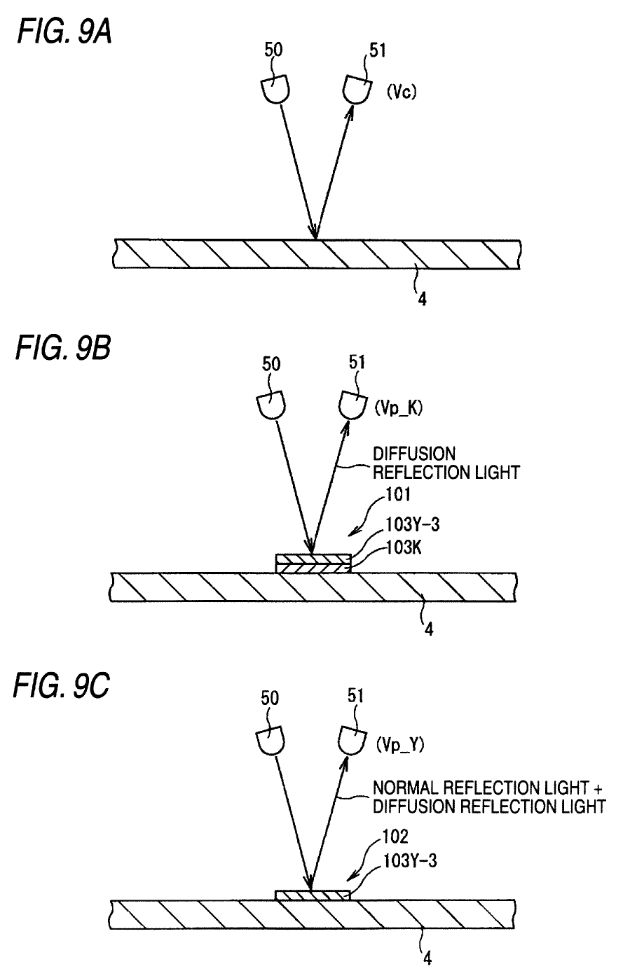

FIGS. 9A to 9C are views showing examples of the output of the density detecting portion in the case where the surface of the intermediate transfer belt, the laminated layer toner patch and the single layer toner patch are respectively irradiated with the irradiation light. The density detecting portion 5 includes: a light emitting element 50 for irradiating the irradiation light onto an object to be detected; a light receiving element 51 for receiving reflection light reflected on an object to be detected in the normal reflecting direction; and a housing for accommodating the light emitting element 50 and the light receiving element 51. The light emitting element 50 and the light receiving element 51 respectively correspond to the light emitting element 50 and the first light receiving element 50A of the first exemplary embodiment.

In FIG. 9A, when the surface of the intermediate transfer belt 4 is irradiated with the irradiation light by the light emitting element, in the same manner as that of FIG. 5A, the light receiving element 51 detects the output value Vc outputted by the reflection light sent from the surface of the intermediate transfer belt 4.

The yellow toner layer 103Y-3 of the laminated layer toner patch 101 exemplarily shown in FIG. 9B is formed, for example, by the intermediate density 50% by the image forming unit 10. In the case where this laminated toner patch 101 is irradiated with the irradiation light, in the same manner as that of FIG. 5B, the irradiation light transmitted through the yellow toner layer 103Y-3 is absorbed by the black toner layer 103K and does not reach the intermediate transfer belt 4. Accordingly, the light receiving element 51 detects the output value Vp_K outputted by the reflection light sent from the yellow toner layer 103Y-3.

The yellow toner layer 103Y-3 of the single layer toner patch 102 exemplarily shown in FIG. 9C is formed by the same intermediate density as that of the laminated layer toner patch 101 shown in FIG. 9B. In the case where this single layer toner patch 102 is irradiated with the irradiation light, in the same manner as that shown in FIG. 5C, the irradiation light transmitted through the yellow toner layer 103Y-3 is reflected by the intermediate transfer belt 4 as the normal reflection light. Therefore, the light receiving element 51 detects the output value Vp_Y outputted by the normal reflection light sent from the intermediate transfer belt 4 and by the diffusion reflection light sent from the yellow toner layer 103Y-3.

Control Portion

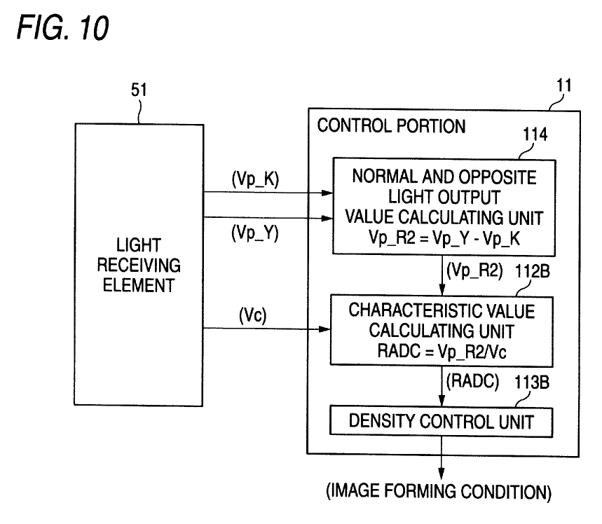

FIG. 10 is a block diagram showing an example of the control system of the image forming apparatus. The control portion 11 includes: a normal reflection light output calculating unit 114; a characteristic value calculating unit 112B; and a density control unit 113B.

Into the normal reflection light output calculating unit 114, the output value Vp_K outputted by the laminated layer toner patch 101 from the light emitting element 51 and the output value Vp_Y outputted by the single layer toner patch 102 are inputted. As shown in the following expression (4), the normal reflection light output calculating unit 114 executes a calculation in which the output value Vp_K is subtracted from the output value Vp_Y, so that the true normal reflection output value Vp_R can be calculated.

Vp_{—}R2=Vp_{—}Y−Vp_{—}K Expression (4)

Into the characteristic value calculating unit 112B, the output value Vc outputted by the surface of the intermediate transfer belt 4 from the light receiving element 51 is inputted. As shown in the following expression (5), when the characteristic value calculating unit 112B executes a calculation in which the true normal reflection light output value Vp_R2 calculated by the normal reflection light output calculating unit 114 is divided by the output value Vc, the detection characteristic value RADC in which the true normal reflection light output value is normalized is calculated.

RADC=(Vp_{—}R2)/Vc Expression (5)

The density control unit 113B calculates an amount of deviation of the density from a difference between the detected density corresponding to the detection characteristic value RADC and the intermediate density at the time of forming the yellow toner layer 103Y-3. Then, the density control unit 113B corrects the image forming condition of the image forming unit 10 so that the amount of deviation of the density can be reduced.

Actions of Image Forming Apparatus

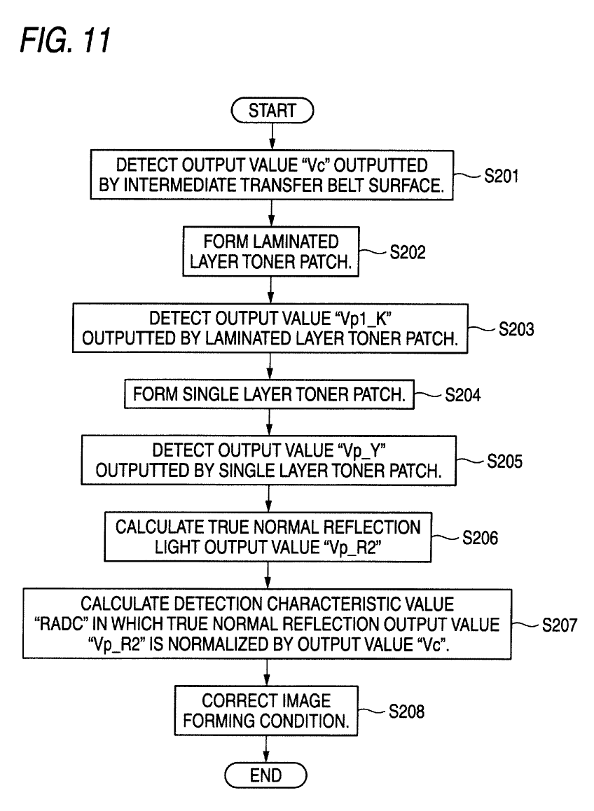

Next, referring to the flow chart shown in FIG. 11, actions of the image forming apparatus 1 will be explained below. First, when the control portion 11 detects a predetermined adjustment timing, the density detecting portion 5 detects an output value Vc outputted by the surface of the intermediate transfer belt 4 is detected as exemplarily shown in FIG. 9A (S201 shown in FIG. 11).

Next, the control portion 11 controls the image forming unit 10 and forms the laminated layer toner patch 101, which is exemplarily shown in FIG. 9B, on the intermediate transfer belt 4 (S202). The density detecting portion 5 detects an output value Vp_K of the reflection light sent from the laminated layer toner patch 101 (S203).

Next, the control portion 11 controls the image forming unit 10 and forms the single layer toner patch 102, which is exemplarily shown in FIG. 9C, on the intermediate transfer belt 4 (S204). The density detecting portion 5 detects an output value Vp_Y of the reflection light sent from the single layer toner patch 102 (S205).

Next, the normal reflection light output calculating unit 114 calculates the true normal reflection light output value Vp_R2 by the above expression (4) by using both the detected outputs Vp_K and Vp_Y (S206).

The characteristic value calculating unit 112B calculates the detection characteristic value RADC by the above expression (3) by using the true normal reflection light output value Vp_R2, which is detected by the normal reflection light output calculating unit 114, and by using the output value Vc (S207). In the same manner as that of the first exemplary embodiment, the density control unit 113B corrects the image forming condition according to the detection characteristic value RADC (S208).

### Third Exemplary Embodiment

The density detecting portion 5 of the image forming apparatus 1 of the present exemplary embodiment includes one light receiving element 51 in the same manner as that of the second exemplary embodiment. However, the correction method of the image forming condition, in which an output value detected by the light receiving element 51 is used, is different. The other basic constitution is the same. Specifically, the control portion 11 of the image forming apparatus 1 of the present exemplary embodiment estimates an output value outputted by the laminated layer toner patch by using the output value outputted by the single layer toner patch detected by the density detecting portion 5. By using the estimated output value, the output value outputted by the laminated layer toner patch detected by the density detecting portion 5 is corrected by using the thus estimated output value. According to the corrected output value outputted by the laminated layer toner patch, the image density is controlled.

Density Detecting Portion

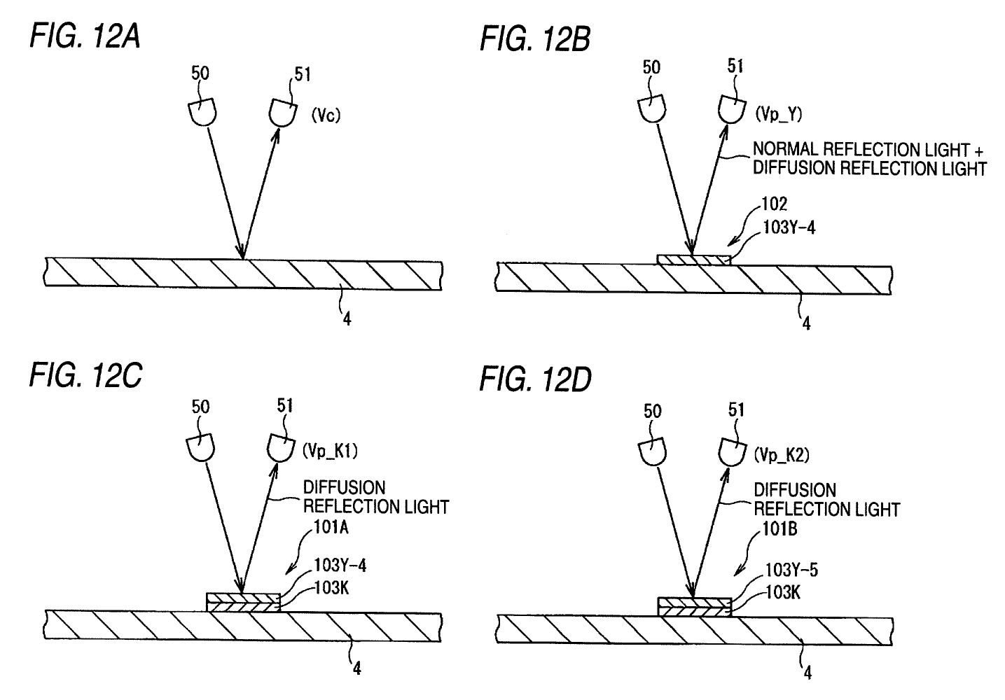

FIGS. 12A to 12D are views showing examples of the output of the density detecting portion in the case where the surface of the intermediate transfer belt, the laminated layer toner patch, the laminated layer toner patch for calculating a coefficient and the laminated layer toner patch for correcting density are respectively irradiated with the irradiation light.

In FIG. 12A, in the same manner as that shown in FIG. 9A, the light receiving element 51 detects an output value Vc of the reflection light sent from the surface of the intermediate transfer belt 4.

The yellow toner layer 103Y-4 of the single layer toner patch 102, which is exemplarily shown in FIG. 12B, is formed by the density D4 for calculating a coefficient by the image forming unit 10. In the case where this single layer toner patch 102 is irradiated with the irradiation light, in the same manner as that shown in FIG. 9C, the light receiving element 51 detects an output value Vp_Y outputted by the normal reflection light sent from the intermediate transfer belt 4 and by the diffusion reflection light sent from the yellow toner layer 103Y-4.

The yellow toner layer 103Y-4 of the laminated layer toner patch 101A for calculating a coefficient exemplarily shown in FIG. 12C is formed by the same density D4 for calculating a coefficient as that of the single layer toner patch 102 shown in FIG. 12B. In the case where this laminated layer toner patch 101A for calculating a coefficient is irradiated with the irradiation light, in the same manner as that shown in FIG. 9B, the light receiving element 51 detects an output value Vp_K1 outputted by the reflection light sent from the yellow toner layer 103Y-4.

The yellow toner layer 103Y-5 of the laminated layer toner patch 101B for correcting density exemplarily shown in FIG. 12D is formed by the density D6 for correction different from the density D4 for calculating a coefficient of the laminated layer toner patch 101A for calculating a coefficient. In the case where this laminated layer toner patch 101B for correcting density is irradiated with the irradiation light, the light receiving element 51 detects an output value Vp_K2 outputted by the reflection light sent from the yellow toner layer 103Y-5.

Control Portion

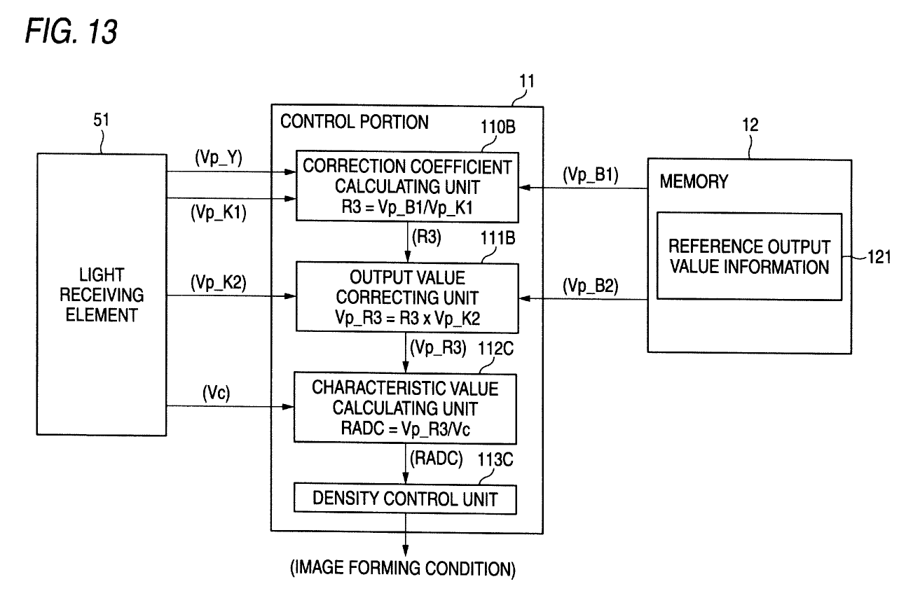

FIG. 13 is a block diagram showing an example of the control system of the image forming apparatus. The control portion 11 includes: a correction coefficient calculating unit 110B; an output value correcting unit 111B; a characteristic value calculating unit 112C; and a density control unit 113C.

When the output value Vp_Y outputted by the single layer toner patch 102 is inputted from the light receiving element 51 into the correction coefficient calculating unit 110B and when the output value Vp_K1 outputted by the laminated layer toner patch 101A for calculating a coefficient is also inputted from the light receiving element 51 into the correction coefficient calculating unit 110B, an estimated density corresponding to the output value Vp_Y is acquired by referring to the reference output value information 121 stored in the memory 12. Next, the correction coefficient calculating unit 110B acquires the reference output value Vp_B1 of the diffusion reflection light corresponding to the acquired estimated density as an estimated output value from the reference output value information 121. Then, as shown in the following expression (6), the correction coefficient calculating unit 110B calculates a sensitivity correcting coefficient R3 when the output value Vp_K1 is divided by the reference output value Vp_B1.

R3=Vp_{—}B1/Vp_{—}K1 Expression (6)

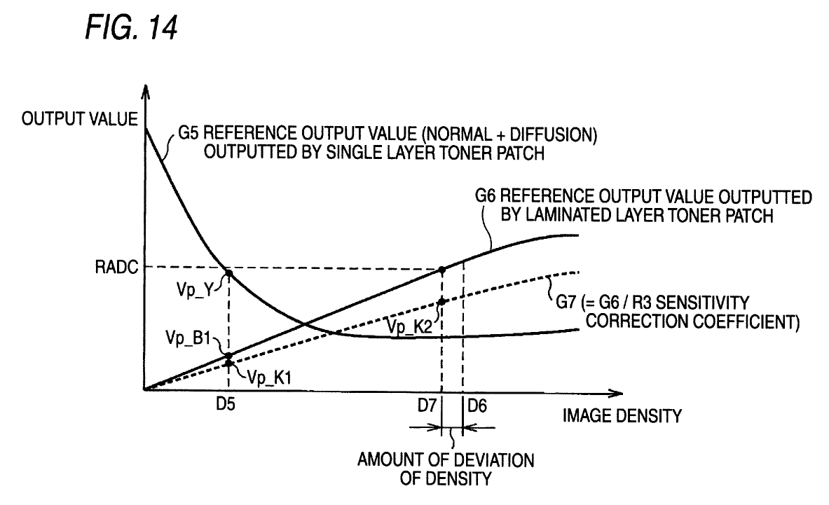

FIG. 14 is a view showing a relation between the image density (the axis of abscissa) and the output value (the axis of ordinate) of the density detecting portion. The graphs G5 and G6 are output values stored as the reference output value information 121, which are the reference sensitivities of the single layer toner patch and the laminated layer toner patch. The output value Vp_Y is plotted on the graph G5 and the correction coefficient calculating unit 110B acquires an estimated density corresponding to the output value Vp_Y. The correction coefficient calculating unit 110B acquires an output value on the graph G6 corresponding to the estimated density D5 from the reference output value information 121 as a reference output value Vp_B1. The correction coefficient calculating unit 10B calculates a sensitivity correction coefficient R3 for correcting the output value of the light receiving element 51 so that the output value Vp_K1 detected from the laminated layer toner patch can be the same as the reference output value Vp_B1 on the graph G6.

Into the output value correcting unit 111B, the output value Vp_K2 outputted by the laminated layer toner patch 101B for correcting density is inputted. As shown in the following expression (7), the output value correcting unit 111B calculates a correction output value Vp_R3 when the output value Vp_K2 is corrected by using the sensitivity correction coefficient R3 calculated by the correction coefficient calculating unit 110A.

Vp_{—}R3=R3×Vp_{—}K2 Expression (7)

The output value Vc outputted by a surface of the intermediate transfer belt 4 is inputted from the light receiving element 51 into the characteristic value calculating unit 112C. As shown in the following expression (8), when the correction output value Vp_R3 corrected by the output value correcting unit 111B is divided by the output value Vc, the characteristic value calculating unit 112C calculates a detection characteristic value RADC in which the correction output value Vp_R3 is made to be a standard.

RADC=Vp_{—}R3/Vc Expression (8)

The density control unit 113C calculates an amount of deviation of density from the difference between the detection density D7, which corresponds to the detection characteristic vale RADC calculated by the characteristic value calculating unit 112A and the density D6 for correction at the time of forming the yellow toner layer 103Y-5. The density control unit 113C corrects the image forming condition of the image forming unit 10 so that the amount of deviation of density can be reduced.

Actions of Image Forming Apparatus

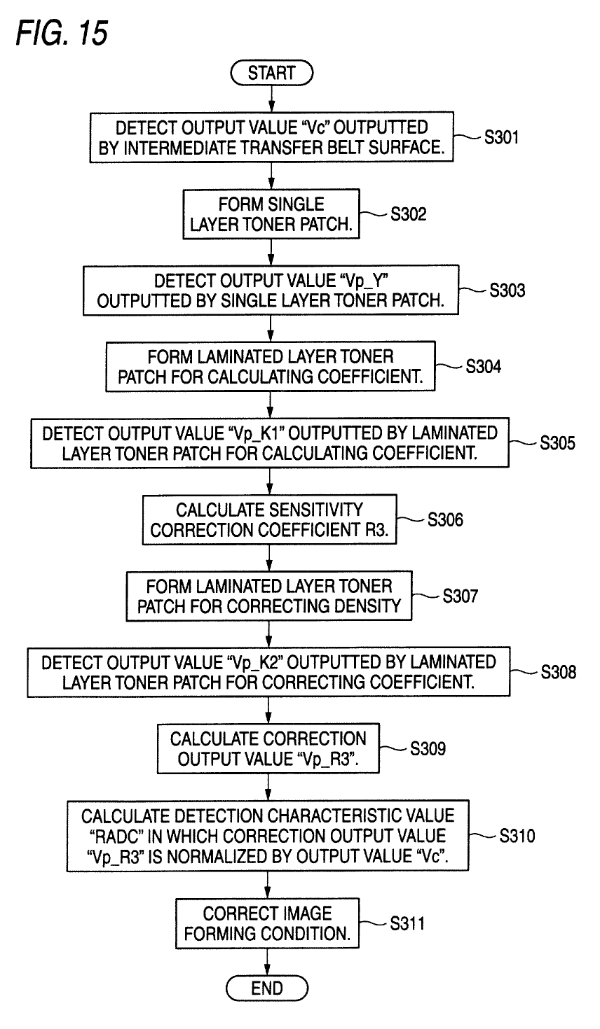

Next, referring to the flow chart shown in FIG. 15, an example of the actions of the image forming apparatus 1 will be explained below. First, when the control portion 11 detects a predetermined adjustment timing, as exemplarily shown in FIG. 12A, the density detecting portion 5 detects an output value Vc from a surface of the intermediate transfer belt 4 (S301 shown in FIG. 15).

Then, the control portion 11 controls the image forming unit 10 and forms a single layer toner patch 102 exemplarily shown in FIG. 12B on the intermediate transfer belt 4 (S302). The density detecting portion 5 detects an output value Vp_Y of the reflection light sent from the single layer toner patch 102 (S303).

Next, the control portion 11 controls the image forming unit 10 and forms a laminated layer toner patch 101A for calculating a coefficient exemplarily shown in FIG. 12C on the intermediate transfer belt 4 (S304). The density detecting portion 5 detects an output value Vp_K1 of the reflection light sent from the laminated layer toner patch 101A for calculating a coefficient (S305).

Next, the correction coefficient calculating unit 110B acquires the estimated density D5 corresponding to the output value Vp_Y referring to the reference output information 121 in the memory 12. The correction coefficient calculating unit 110B acquires a reference output value Vp_B1 of the diffusion reflecting light, which corresponds to the acquired estimated density D5, from the reference output value information 121. Then, the correction coefficient calculating unit 110B calculates a sensitivity correction coefficient R3 by the above expression (6) by using the output value Vp_K1 and the reference output value Vp_B1 (S306).

After that, when the image data is inputted, before an image according to the image data is formed, the control portion 11 controls the image forming unit 10 and forms a laminated layer toner patch 101B for correcting density, which is exemplarily shown in FIG. 12D, on the intermediate transfer belt 4 (S307). Then, the density detecting portion 5 detects an output value Vp_K2 outputted by the laminated layer toner patch 101B for correcting density (S308).

Then, the output value correcting unit 111B calculates a correction output value Vp_R3 by the above expression (7) by using the detected output value Vp_K2 and the coefficient R3 for correcting sensitivity (S309).

Next, the characteristic value calculating unit 112C calculates a detection characteristic value RADC, in which the correction output value Vp_R3 is normalized, by the above expression (8) (S310). The density control unit 113C corrects the image forming condition on the basis of the detection characteristic value RADC (S311)

As described above, the image forming apparatus 1 forms an image according to the image data inputted under the condition that the image forming condition has been corrected.

### Another Exemplary Embodiment

In this connection, it should be noted that the present invention is not limited to the above specific exemplary embodiment but variations can be made without departing from the spirit and the scope of the claim of the invention. For example, in each exemplary embodiment described above, the correction coefficient calculating unit, the output value correcting unit, the characteristic value calculating unit, the density control unit and the normal reflection light output calculating unit, which are included in the control portion of the image forming apparatus, may be realized by a program to operate the control portion. Alternatively, some or all of the unit described above may be realized by the hardware.

The above program may be read from a recording medium such as CD-ROM into the memory provided in the image forming apparatus. Alternatively, the above program may be downloaded from a server connected to the network such as the Internet into the memory provided in the image forming apparatus.

In the laminated layer toner patch related to each exemplary embodiment described above, black toner is used for the first color layer and yellow toner is used for the second color layer. However, magenta toner, cyan toner, red toner, green toner, blue toner or transparent toner (This is toner which becomes transparent after the completion of fixing.) may be used for the second color layer. The laminated layer toner patch may be composed in such a manner that three or more color layers are laminated on each other. In this case, black toner is used for the lowermost color layer and toner except for black toner may be used for the coloring mater layers except for the lowermost layer. In the single layer toner patch, magenta toner, cyan toner, red toner, green toner, blue toner or transparent toner (This is toner which becomes transparent after the completion of fixing.) may be used.

The wave-length of the irradiation light emitted by the density detecting portion may be changed according to the reflection characteristic of toner used for the laminated toner patch. For example, in the case where cyan toner is used for the first coloring mater layer instead of black toner and in the case where yellow toner or magenta toner is used for the second color layer, as exemplarily shown in FIG. 2, since the reflectance of yellow toner or magenta toner is higher than the reflectance of cyan toner in the wave-length region of 600 to 700 nm, the light emitting element of the density detecting portion may be composed so that it can irradiate irradiation light of 650 nm. Further, toner used for the laminated toner patch may be changed according to the wave-length of the irradiation light emitted from the density detecting portion.

In the exemplary embodiments described above, in the flow charts exemplarily shown in FIGS. 8, 11 and 15, as long as the same processing result can be obtained, the order of the steps may be changed. Alternatively, the steps may be executed in parallel with each other.

In each exemplary embodiment described above, the image forming apparatus of the rotary type is explained. However, it is possible to apply the present invention to a tandem type image forming apparatus. It is also possible to apply the present invention to an image forming apparatus in which a photoreceptor belt is used instead of a photoreceptor drum.

In the exemplary embodiments described above, colors of toner used for the image forming apparatus are not limited to the three primary colors YMC. For example, the present invention can be applied to a case in which a special color (for example, a color of red seal ink) is used for the patch in the image forming apparatus of plus-one-color or multiple color.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The exemplary embodiments were chosen and described in order to best explain the principles of the invention and its practical applications, thereby enabling others skilled in the art to understand the invention for various exemplary embodiments and with the various modifications as are suited to the particular use contemplated. It is intended that the scope of the invention be defined by the following claims and their equivalents.

What is claimed is:

1. An image density control device comprising:
a light irradiation unit that irradiates an irradiation light of a wave-length, in which reflectance of a second color layer is higher than reflectance of a first color layer, onto an image which is a laminated layer image formed by an image forming unit on an image carrier and formed out of the first color layer and the second color layer laminated on the first color layer;
a detection unit that detects a quantity of a reflection light reflected on the laminated layer image irradiated by the irradiation light from the light irradiation unit; and
a control unit that controls density of the image according to the quantity of the reflection light detected by the detection unit.

2. The image density control device according to claim 1, wherein the laminated layer image includes the first color layer made of a black coloring matter and the second color layer made of at least one of coloring matters of yellow, magenta and cyan.

3. The image density control device according to claim 1, wherein the irradiation light from the light irradiation unit is an infrared light.

4. The image density control device according to claim 1, wherein
the light irradiation unit irradiates the irradiation light onto a single layer image formed out of the second color layer on the image carrier by the image forming unit,
the detection unit further detects a quantity of another reflection light reflected on the single layer image irradiated by the irradiation light from the light irradiation unit, and
the control unit corrects the quantity of the another reflection light reflected on the single layer image by using the quantity of the reflection light reflected on the laminated layer image detected by the detection unit and the control unit controls density of the image according to the corrected quantity of the another reflection light reflected by the single layer image.

5. The image density control device according to claim 1, wherein
the light irradiation unit irradiates the irradiation light onto a single layer image formed out of the second color layer on the image carrier by the image forming unit,
the detection unit further detects a quantity of another reflection light reflected on the single layer image irradiated by the irradiation light from the light irradiation unit, and
the control unit estimates the quantity of the reflection light reflected on the laminated layer image by using the quantity of the another reflection light reflected on the single layer image detected by the detection unit and the control unit further corrects a quantity of the another reflection light reflected on the laminated layer image detected by the detection unit by using the estimated reflection light, and the control unit furthermore controls density of the image according to the corrected quantity of the reflection light reflected on the laminated layer image.

6. An image density control device comprising:
a light irradiation unit that irradiates an irradiation light of the wave-length, in which the reflectance of a second color layer is higher than the reflectance of a first color layer, onto an image which is a laminated layer image formed by an image forming unit on an image carrier and formed out of the first color layer and the second color layer laminated on the first color layer;
a first detection unit that detects a quantity of a first reflection light reflected in a normal reflecting direction on the laminated layer image by the irradiation light from the light irradiation unit;
a second detection unit that detects a quantity of a second reflection light reflected in a diffusion reflecting direction on the laminated layer image by the irradiation light from the light irradiation unit; and
a control unit that controls density of the image formed on the image carrier by the image forming unit according to quantities of the first and the second reflection light respectively detected by the first and the second detection unit.

7. The image density control device according to claim 6, wherein the laminated layer image includes the first color layer made of a black coloring matter and also includes the second color layer made of at least one of coloring matters of yellow, magenta and cyan.

8. The image density control device according to claim 6, wherein the irradiation light from the light irradiation unit is infrared light.

9. The image density control device according to claim 6, wherein the control unit corrects one of or both of the quantities of the first and the second reflection light so that the quantities of the first and the second reflection light respectively detected by the first and the second detection unit are the same value, and the control unit controls the density of the image according to the corrected quantities of the first and the second reflection light.

10. The image density control device according to claim 6, wherein
the light irradiation unit irradiates the irradiation light onto a single layer image formed out of the second color layer on the image carrier by the image forming unit,
the first detection unit further detects a quantity of a third reflection light reflected in the normal reflecting direction on the single layer image irradiated by the irradiation light from the light irradiation unit,
the second detection unit furthermore detects a quantity of a fourth reflection light reflected in the diffusion reflecting direction on the single layer image irradiated by the irradiation light from the light irradiation unit, and
the control unit corrects the quantity of the fourth reflection light detected by the second detection unit by using quantities of the first and the third reflection light detected by the first detection unit and also by using the quantity of the second reflection light detected by the second detection unit and the control unit further controls density of the image according to the corrected quantity of the fourth reflection light.

11. An image forming apparatus comprising:
an image carrier that carries an image;
an image forming unit that forms a laminated layer image, which is formed out of a first color layer and a second color layer laminated on the first color layer, on the image carrier;
a light irradiation unit that irradiates light of a wave-length, in which reflectance of the second color layer is higher than reflectance of the first color layer, onto the laminated layer image formed by the image forming unit;
a detection unit that detects a quantity of the reflection light reflected on the laminated layer image irradiated by the irradiation light from the light irradiation unit; and
a control unit that controls density of the image formed on the image carrier by the image forming unit according to the quantity of the reflection light detected by the detection unit.

12. An image forming apparatus comprising:
an image carrier that carries an image;
an image forming unit that forms a laminated layer image, which is formed out of a first color layer and a second color layer laminated on the first color layer, on the image carrier;
a light irradiation unit that irradiates light of a wave-length, in which reflectance of the second color layer is higher than reflectance of the first color layer, onto the laminated layer image formed by the image forming unit;
a first detection unit that detects a quantity of the first reflection light from the reflection light reflected in a normal reflecting direction on the laminated layer image irradiated by the irradiation light from the light irradiation unit;
a second detection unit that detects a quantity of the second reflection light from the reflection light reflected in a diffusion reflecting direction on the laminated layer image irradiated by the irradiation light from the light irradiation unit; and
a control unit that controls density of the image formed on the image carrier by the image forming unit according to the quantities of the first and the second reflection light respectively detected by the first and the second detection unit.
